(19) United States
(12) Patent Application Publication
(10) Pub. No.: US 2006/0263724 A1
(43) Pub. Date: Nov. 23, 2006

(54) METHOD FOR FORMING MATERIAL LAYER BETWEEN LIQUID AND PHOTORESIST LAYER

(76) Inventor: Joseph Chen, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,554

(22) Filed: May 17, 2005

(51) Int. Cl. G03F 7/20

(52) U.S. Cl. 430/311

(57) ABSTRACT

The invention is directed towards a method for forming a material layer between the liquid and the photoresist layer in immersion lithography. After forming a photoresist layer over the wafer, a material layer is formed between the photoresist layer and the liquid and covering the photoresist layer. The material layer, acting as an interface layer and a barrier layer, can provide a first surface wettable to the liquid (or water), and a second surface opposite to the first surface for good adhesion toward the photoresist layer.

### BACKGROUND OF THE INVENTION

1. Field of Invention

The present invention relates to a method for immersion lithography. More particularly, the present invention relates to a method for forming a material layer between the liquid and the photoresist layer in immersion lithography.

2. Description of Related Art

In the semiconductor fabrication process, as the dimension of devices on a chip becomes smaller, the resolution required for lithography needs to be higher. Therefore, an emerging technology that uses the refractive properties of fluids to improve the resolution of lithography, called immersion lithography, has been developed in semiconductor manufacturing. In immersion lithography, a liquid is interposed between an exposure tool's projection lens and the surface of the wafer. Usually, for 193 nm immersion lithography, water appears to be the best medium for this purpose. Immersion technology offers better resolution over conventional projection lithography because the lens can be designed with numerical apertures greater than one, which create the ability to produce smaller features. Immersion lithography can provide a number of advantages, including effectively decreasing the wavelength of the exposure light and providing a considerable boost to the focus depth.

However, for the immersion lithography technology, certain technical problems still exist, such as bubbles in the immersion water or the reaction of the photoresist or the lens material to water. Bubbles can be introduced during a variety of steps in the immersion lithography process. They can come from air trapped in wafer topography, for instance, or arise from the thermal effect created by the tool's laser pulse. Or they can occur during the injection or removal of the fluid from the space between lens and wafer. Similarly, during the immersion lithography process, since the liquid is placed between the lens and the wafer and in contact with the photoresist layer over the wafer, further reaction may occur between the liquid and the photoresist layer and cause defects for lithography.

Therefore, there is a need to develop an approach in immersion lithography technology to alleviate the bubble issue or the inter-reaction issue.

### SUMMARY OF THE INVENTION

It is therefore an object of the invention to provide a method for forming a material layer between the liquid and the photoresist layer in immersion lithography. The problems of micro-bubbles between the photoresist and the liquid can be alleviated, and further reaction between the photoresist and the liquid can be avoided.

To achieve these objects and advantages, and in accordance with the purpose of the invention, as embodied and broadly described herein, the invention is directed towards a method for forming a material layer between the liquid and the photoresist layer in immersion lithography. After forming a photoresist layer over the wafer, a material layer is formed on the photoresist layer and covering the photoresist layer. The material layer can be formed by spin-coating, for example. The material layer can provide a first surface wettable to the liquid (or water), and a second surface opposite to the first surface for good adhesion toward the photoresist layer. Afterwards, a liquid is provided between the material layer and a lens element of the immersion lithography system and covering the material layer.

Through forming the material layer as an interface layer between the liquid and the photoresist layer, the material layer provides good wetting toward the liquid, as well as excellent adhesion toward the photoresist layer. In addition, the material layer can act as a barrier layer, so that the molecules or particulates in the photoresist layer will not diffuse out into the liquid. Hence, the problems of bubbles or inter-reaction between the liquid and the photoresist layer can be solved and the pattern fidelity can be improved due to less defects.

Furthermore, the material layer of this invention can function as a top anti-reflection coating (ARC) layer for improving resolution of the lithography process. In this case, the material layer can be removed at the same time as the photoresist layer is developed.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are cross-sectional views of the process steps for forming a material layer according to one preferred embodiment of this invention.

FIG. 2 is a cross-sectional view of the process step for forming a material layer according to another preferred embodiment of this invention.

### DESCRIPTION OF THE PREFERRED EMBODIMENTS

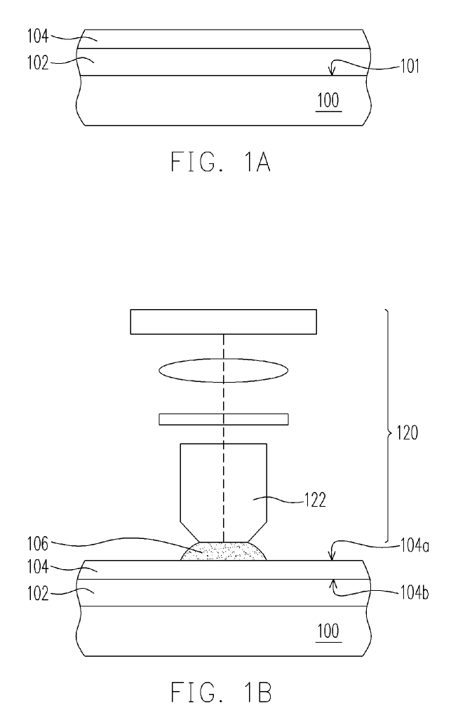

FIGS. 1A-1B are cross-sectional views of the process steps for forming a material layer according to one preferred embodiment of this invention.

Referring to FIG. 1A, a semiconductor substrate or a semiconductor wafer 100 having a plurality of different material layers (not shown) thereon is provided. A photoresist layer 102 is formed over the active surface 101 of the wafer 100 by, for example, spin-coating. The photoresist layer 102 can be a positive photoresist layer or a negative photoresist layer. Afterwards, a material layer 104 is formed on the photoresist layer 102 and covering the photoresist layer 102. The material layer 104 can be formed by spin-coating or deposition, for example. Preferably, if the photoresist layer 102 is a 193 nm photoresist layer, the material layer 104 can be a 248 nm photoresist layer, for example. Alternatively, the material layer 104 may be comprised of a top anti-reflection coating (ARC) layer and the top ARC layer is made of fluid organic polymer, for example. The material of the material layer 104 needs to adhere tightly to the photoresist layer 102 but not to intermix with the photoresist layer 102.

As shown in FIG. 1B, a liquid 106 is provided to cover the material layer 104 and the liquid 106 is filled between the material layer and a lens element 122 of the immersion lithography system 120. The first surface 104a of the material layer 104 is in contact with the liquid 106 and is wettable to the liquid 106, while the second surface 104b of the material layer 104 is in contact with the photoresist layer 102 and provides good adhesion to the photoresist layer 102.

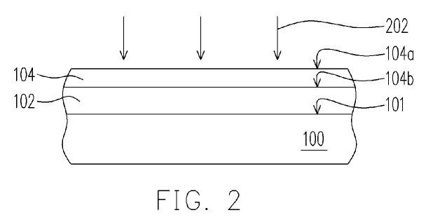

In order to achieve wettability of the material layer 104 toward the liquid 106, the first surface 104a of the material layer 104 may include a plurality of functional groups to provide wettablity to the liquid 106. For example, if the liquid is water or a hydrophilic solvent, the first surface 104a of the material layer 104 may include a plurality of hydroxyl functional groups to provide wettablity. Moreover, the material layer 104 can be further treated with a surface treatment 202 after forming the material layer so as to increase the wettability of the first surface, as shown in FIG. 2. The surface treatment 202 may include treating the first surface 104a of the material layer 104 with an oxygen-containing plasma, such as N2O plasma, or treating the material layer 104 with an oxidizing agent, such as ozone or other suitable chemical agents.

After the exposure step of the immersion lithography, latent patterns are formed in the photoresist layer 102 and the development step is followed. During the development step, the material layer 104 can be removed at the same time as the photoresist layer 102 is developed. Because the material of the material layer 104 is soluble to a developer for the photoresist layer, so that the material layer is removed along with the photoresist layer 102.

The following processes are well known to persons skilled in the art, and will not be further described therein.

The material layer described in this invention can act as an interface layer between the liquid and the photoresist layer for better adhesion to the photoresist layer and enhanced wettability toward the liquid, as well as a barrier layer for preventing impurities or particulates diffusing out from the photoresist layer. Moreover, the material layer can act as a top ARC layer for improved resolution.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a material layer between a liquid and a photoresist layer in an immersion lithography system, comprising:
providing a wafer;
forming a photoresist layer over the wafer;
forming a material layer on the photoresist layer and covering the photoresist layer, wherein the material layer includes a first surface and a second surface opposite to the first surface;
providing a liquid covering the material layer and between the material layer and a lens element of the immersion lithography system, wherein the first surface of the material layer is in contact with the liquid and is wettable to the liquid, while the second surface of the material layer is in contact with the photoresist layer and provides adhesion to the photoresist layer.

2. The method as claimed in claim 1, wherein if the liquid is water, the first surface of the material layer includes a plurality of hydroxyl functional groups to provide wettablity.

3. The method as claimed in claim 1, wherein a method for forming the material layer includes spin-coating.

4. The method as claimed in claim 1, wherein the step of forming the material layer comprises forming a top anti-reflection coating (ARC) layer.

5. The method as claimed in claim 4, wherein the top ARC layer is made of fluid organic polymer.

6. The method as claimed in claim 1, wherein if the photoresist layer is a 193 nm photoresist layer, the material layer is a 248 nm photoresist layer.

7. The method as claimed in claim 6, wherein the material layer is removed at the same time as the photoresist layer is developed.

8. The method as claimed in claim 1, wherein a material of the material layer is soluble to a developer for the photoresist layer, so that the material layer is removed at the same time as the photoresist layer is developed.

9. The method as claimed in claim 1, wherein the step of forming the material layer further comprises treating the material layer with a surface treatment after forming the material layer so as to increase the wettability of the first surface.

10. The method as claimed in claim 1, wherein the surface treatment includes treating the material layer with an oxygen-containing plasma.

11. The method as claimed in claim 1, wherein the surface treatment includes treating the material layer with ozone.

12. The method as claimed in claim 1, wherein the surface treatment includes treating the material layer with an oxidizing agent.
